(19) United States
(12) Patent Application Publication
(10) Pub. No.: US 2026/0305417 A1
(43) Pub. Date: Oct. 1, 2026

(54) SEMICONDUCTOR DEVICE

(71) Applicant: FUJI ELECTRIC CO., LTD., Kawasaki-shi (JP)

(72) Inventor: Taichi ITOH, Matsumoto-city (JP)

(73) Assignee: FUJI ELECTRIC CO., LTD., Kawasaki-shi (JP)

(21) Appl. No.: 19/549,793

(22) Filed: Feb. 25, 2026

(30) Foreign Application Priority Data
Mar. 25, 2025 (JP) 2025-050230

(51) Int. Cl. H10W 70/654; H10W 70/60; H10W 90/00; H10W 90/10

(52) U.S. Cl. CPC H10W 70/654; H10W 70/614; H10W 90/10; H10W 90/753; H10W 90/754

(57) ABSTRACT

A semiconductor device, including first and second semiconductor chips, an output terminal, a positive terminal, a negative terminal, and an insulated circuit substrate. The insulated circuit substrate has first to third conductive circuit pattern disposed on an insulating plate. The first conductive circuit pattern includes a first mounting portion on which the first semiconductor chip is mounted, and a first terminal portion to which the output terminal is bonded. The second conductive circuit pattern includes a second mounting portion on which the second semiconductor chip is mounted, and a second terminal portion to which the positive terminal is bonded. The third conductive circuit pattern includes a third terminal portion to which the negative terminal is bonded. The first and second mounting portions have a gap therebetween. The first to third terminal portions are sequentially arranged in the gap on the upper surface of the insulating plate.

### CROSS-REFERENCE TO RELATED APPLICATION(S)

This application is based upon and claims the benefit of priority of the prior Japanese Patent Application No. 2025-050230, filed on Mar. 25, 2025, the entire contents of which are incorporated herein by reference.

### BACKGROUND OF THE INVENTION

### 1. Field of the Invention

The embodiments discussed herein relate to a semiconductor device.

### 2. Background of the Related Art

A semiconductor device includes a plurality of conductive circuit patterns and a plurality of semiconductor chips. The plurality of semiconductor chips are disposed on predetermined conductive circuit patterns among the plurality of conductive circuit patterns. In addition, the plurality of semiconductor chips and the plurality of conductive circuit patterns are electrically wired as appropriate. A semiconductor device having such a configuration has a power conversion function (see, for example, Japanese Laid-open Patent Publication No. 2002-203942 and Japanese Laid-open Patent Publication No. 2013-098425).

### SUMMARY OF THE INVENTION

According to an aspect of the present disclosure, there is provided a semiconductor device, including: a first semiconductor chip having a lower surface and an upper surface; a second semiconductor chip having a lower surface and an upper surface; an output terminal, a positive terminal, and a negative terminal; and an insulated circuit substrate, including: an insulating plate having an upper surface, the insulating plate having a first side and a second side opposite to each other in a plan view of the semiconductor device, and a first conductive circuit pattern, a second conductive circuit pattern, and a third conductive circuit pattern that are disposed on the upper surface of the insulating plate, wherein the first conductive circuit pattern includes: a first mounting portion on which the lower surface of the first semiconductor chip is mounted, and a first terminal portion to which the output terminal is bonded; the second conductive circuit pattern includes: a second mounting portion on which the lower surface of the second semiconductor chip is mounted, and a second terminal portion to which the positive terminal is bonded; the third conductive circuit pattern includes a third terminal portion to which the negative terminal is bonded; the first mounting portion of the first conductive circuit pattern is located adjacent to the first side of the insulating plate, and the second mounting portion of the second conductive circuit pattern is located adjacent to the second side of the insulating plate, the first mounting portion and the second mounting portion having a gap therebetween; and the first terminal portion, the second terminal portion, and the third terminal portion are sequentially arranged, parallel to the first side and the second side, in the gap on the upper surface of the insulating plate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF THE DRAWINGS

FIG. 1 is a plan view of a semiconductor device according to a first embodiment;

FIG. 2 is a side view of the semiconductor device according to the first embodiment;

FIG. 3 is a plan view of the semiconductor device (excluding a case and bonding wires) according to the first embodiment;

FIG. 4 is a plan view of the semiconductor device (excluding a case, bonding wires, and lead frames) according to the first embodiment;

FIG. 5 is a plan view of a semiconductor unit included in the semiconductor device according to the first embodiment;

FIG. 6 is a plan view of an insulated circuit substrate of the semiconductor unit included in the semiconductor device according to the first embodiment;

FIG. 7 is a plan view of a semiconductor unit included in a semiconductor device according to a second embodiment; and

FIG. 8 is a plan view of a semiconductor unit included in a semiconductor device according to a third embodiment.

### DETAILED DESCRIPTION OF THE INVENTION

Hereinafter, embodiments will be described with reference to the drawings. Throughout the following embodiments, the term “upper surface” refers to a surface facing upward on the plane of the paper. Similarly, the terms “up”, “upper portion”, and “above” refer to an upward direction on the plane of the paper. In addition, the term “lower surface” refers to a surface facing downward on the plane of the paper. Similarly, the terms “down”, “lower portion”, and “below” refer to a downward direction on the plane of the paper. These directional indications apply to all drawings. The terms “upper surface”, “up”, “upper portion”, “above”, “down”, “lower surface”, “lower portion”, and “below” are merely used for convenience in describing relative positional relationships, and do not limit the technical concept of the present disclosure. In addition, throughout the following embodiments, the term “main component” refers to a component contained in an amount of 80 vol % or more. Similarly, the expression “substantially the same” is intended to include variations within a range of ±10%. The terms “perpendicular”, “orthogonal”, and “parallel” are intended to include deviations within ±10°.

### First Embodiment

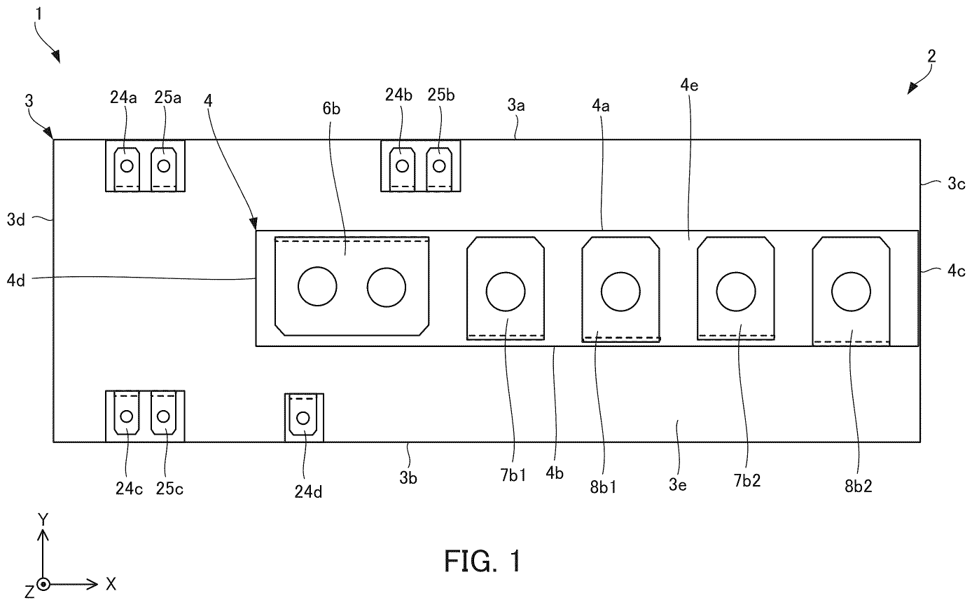

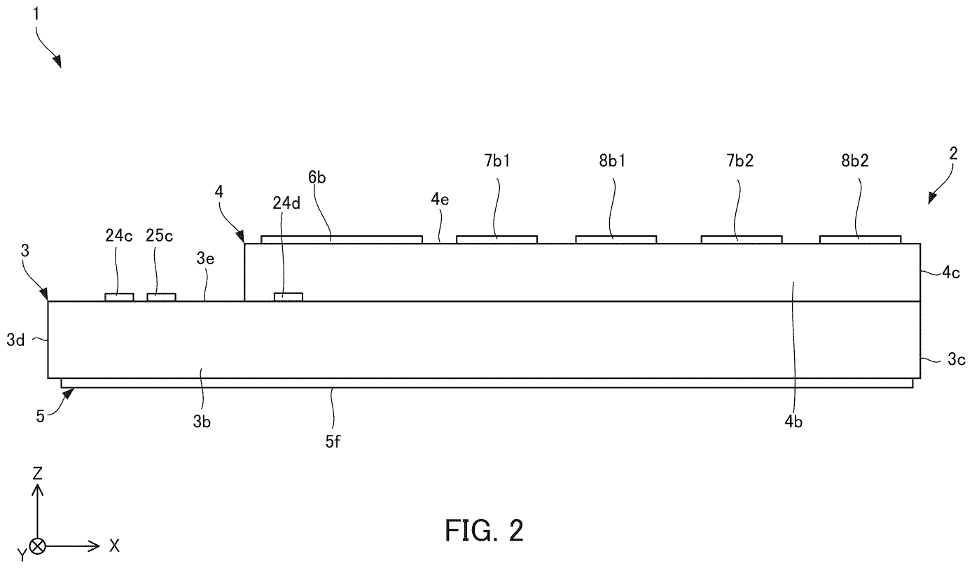

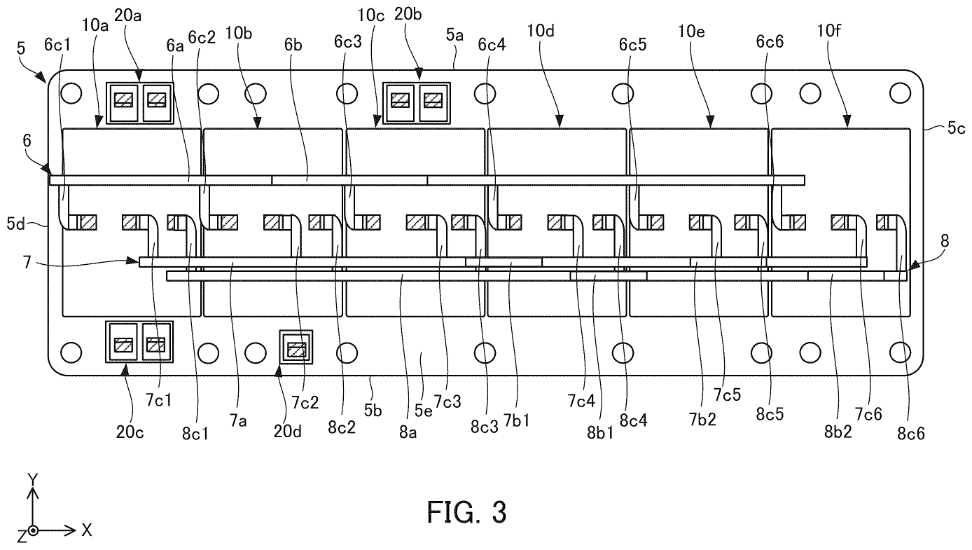

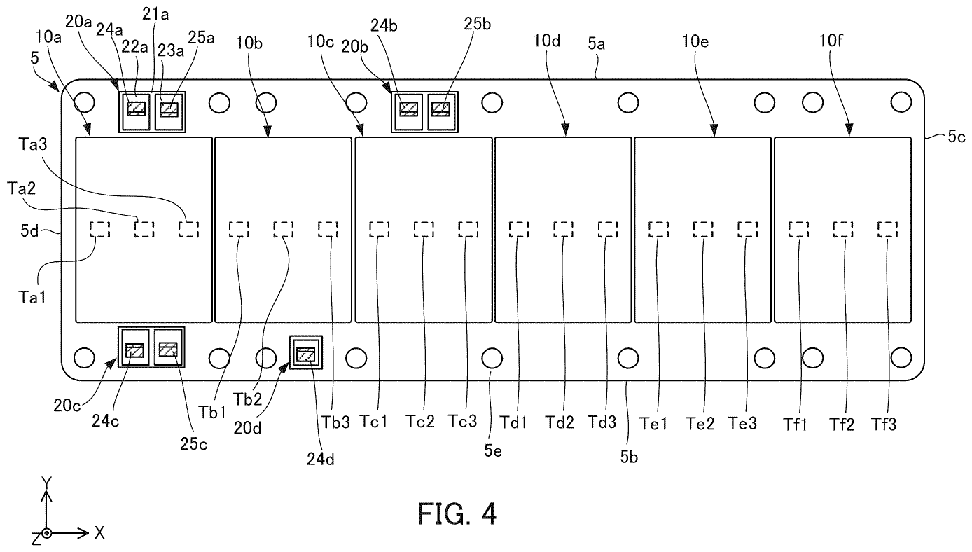

A semiconductor device will be described with reference to FIGS. 1 to 4. FIG. 1 is a plan view of a semiconductor device according to a first embodiment. FIG. 2 is a side view of the semiconductor device according to the first embodiment. FIG. 3 is a plan view of the semiconductor device (excluding a case and bonding wires) according to the first embodiment. FIG. 4 is a plan view of the semiconductor device (excluding the case, bonding wires, and lead frames) according to the first embodiment.

The side view of the semiconductor device 1 illustrated in FIG. 2 corresponds to a side portion 3b and a side portion 4b of the semiconductor device 1 in FIG. 1. A terminal portion 6b of a lead frame 6 illustrated in FIG. 3 is not bent but extends upward (+Z direction). A terminal portion 7b1 and a terminal portion 7b2 of a lead frame 7 illustrated in FIG. 3 are not bent but extend upward (+Z direction). A terminal portion 8b1 and a terminal portion 8b2 of a lead frame 8 illustrated in FIG. 3 are not bent but extend upward (+Z direction). FIGS. 3 and 4 schematically illustrate a plurality of semiconductor units.

The semiconductor device 1 includes a heat dissipation base 5 and a case 2. The semiconductor device 1 further includes a plurality of semiconductor units, a plurality of control wiring units, an output terminal, a positive terminal, and a negative terminal. The plurality of semiconductor units and the plurality of control wiring units are disposed on the heat dissipation base 5. The output terminal is electrically connected to the plurality of semiconductor units. The positive terminal is electrically connected to the plurality of semiconductor units. The negative terminal is electrically connected to the plurality of semiconductor units.

The plurality of semiconductor units may be, for example, semiconductor units 10a, 10b, 10c, 10d, 10e, and 10f. The plurality of control wiring units may be, for example, control wiring units 20a, 20b, 20c, and 20d. The output terminal may be, for example, the lead frame 6. The positive terminal may be, for example, the lead frame 7. The negative terminal may be, for example, the lead frame 8.

The case 2 integrally includes a lower housing 3 and an upper housing 4. The lower housing 3 has a cuboid box shape and does not include a lower surface. The lower housing 3 includes side portions 3a, 3b, 3c, 3d and an upper surface 3e. The upper surface 3e has a rectangular shape in plan view. The shape of the upper surface 3e may correspond to that of the upper surface 5e of the heat dissipation base 5. The size of the upper surface 3e may be the same as that of the heat dissipation base 5. Alternatively, the size of the upper surface 3e may be slightly larger than that of the heat dissipation base 5. The upper housing 4 is integrally formed on the upper surface 3e. A portion of the upper surface 3e where the upper housing 4 is formed is open. That is, the space inside the lower housing 3 and the space inside the upper housing 4 are continuous.

Terminal portions 24a and 25a of the control wiring unit 20a, which will be described later, are provided on the upper surface 3e. On the upper surface 3e, the terminal portions 24a and 25a are arranged along the side portion 3a and are located close to the side portion 3d. The terminal portions 24a and 25a initially extend upward (+Z direction). When the case 2 is attached to the heat dissipation base 5, the terminal portions 24a and 25a penetrate through the upper surface 3e of the case 2 and extend upward (+Z direction). Portions of the terminal portions 24a and 25a extending from the upper surface 3e are bent, so that the terminal portions 24a and 25a are placed on the upper surface 3e as illustrated in FIG. 1.

Terminal portions 24b and 25b of the control wiring unit 20b, which will be described later, are provided on the upper surface 3e. On the upper surface 3e, the terminal portions 24b and 25b are arranged along the side portion 3a and are located on the side of the terminal portions 24a and 25a opposite to the side portion 3d. The terminal portions 24b and 25b are also bent in the same manner as described above, so that they are placed on the upper surface 3e.

Terminal portions 24c and 25c of the control wiring unit 20c, which will be described later, are provided on the upper surface 3e. On the upper surface 3e, the terminal portions 24c and 25c are arranged along the side portion 3b and are located close to the side portion 3d. The terminal portions 24c and 25c are also bent in the same manner as described above, so that they are placed on the upper surface 3e.

A terminal portion 24d of the control wiring unit 20d, which will be described later, is provided on the upper surface 3e. On the upper surface 3e, the terminal portion 24d is placed along the side portion 3b, and is located on the side of the terminal portions 24c and 25c opposite to the side portion 3d. The terminal portion 24d is also bent in the same manner as described above, so that it is placed on the upper surface 3e.

Each of the side portions 3a, 3b, 3c, and 3d may have a flat plate shape. The side portions 3a, 3b, 3c, and 3d surround the four sides of the upper surface 3e. The connection portion between the side portion 3a and the side portion 3c, the connection portion between the side portion 3c and the side portion 3b, the connection portion between the side portion 3b and the side portion 3d, and the connection portion between the side portion 3a and the side portion 3d correspond to the four corner portions of the lower housing 3 in plan view. The side portions 3a, 3b, 3c, and 3d have the same height (the thickness of the lower housing 3). The side portions 3a and 3b extend along the long-side direction of the upper surface 3e. The side portions 3c and 3d extend along the short-side direction of the upper surface 3e.

The upper housing 4 has a cuboid box shape and does not include a lower surface. The upper housing 4 is provided integrally with the lower housing 3. The upper housing 4 is provided on a center line parallel to the side portions 3a and 3b on the upper surface 3e in plan view. The side portion 4c of the upper housing 4 and the side portion 3c of the lower housing 3 are flush with each other.

The upper housing 4 includes side portions 4a, 4b, 4c, 4d and an upper surface 4e. The upper surface 4e has a rectangular shape in plan view. The area of the upper surface 4e is smaller than that of the upper surface 3e. That is, the upper surface 4e is shorter in the long-side direction than the upper surface 3e, and is shorter in the short-side direction than the upper surface 3e.

The terminal portion 6b (for output) of the lead frame 6, which will be described later, is provided on the upper surface 4e. On the upper surface 4e, the terminal portion 6b is located close to the side portion 4d. Before the case 2 is attached, the terminal portion 6b extends upward (+Z direction). When the case 2 is attached to the heat dissipation base 5, the terminal portion 6b penetrates through the upper surface 4e of the case 2 and extends upward (+Z direction). A portion of the terminal portion 6b extending from the upper surface 4e is bent, so that the terminal portion 6b is placed on the upper surface 4e as illustrated in FIG. 1.

The terminal portions 7b1 and 7b2 (for positive electrode) of the lead frame 7, which will be described later, are provided on the upper surface 4e. The terminal portions 8b1 and 8b2 (for negative electrode) of the lead frame 8, which will be described later, are provided on the upper surface 4e. The terminal portions 7b1, 8b1, 7b2, and 8b2 are arranged in that order in a direction from the terminal portion 6b toward the side portion 4c, on the upper surface 4e in plan view. The terminal portions 7b1, 8b1, 7b2, and 8b2 are also bent in the same manner as described above, so that they are placed on the upper surface 4e.

Each of the side portions 4a, 4b, 4c, and 4d may have a flat plate shape. The side portions 4a, 4b, 4c, and 4d surround the four sides of the upper surface 4e. The connection portion between the side portion 4a and the side portion 4c, the connection portion between the side portion 4c and the side portion 4b, the connection portion between the side portion 4b and the side portion 4d, and the connection portion between the side portion 4d and the side portion 4a correspond to the four corner portions of the upper housing 4 in plan view. The side portions 4a, 4b, 4c, and 4d have the same height (the thickness of the upper housing 4). The side portions 4a and 4b extend along the long-side direction of the upper surface 4e. The side portions 4c and 4d extend along the short-side direction of the upper surface 4e. Each of the side portions 4a, 4b, 4c, 4d may be integrally connected to the upper surface 3e of the lower housing 3.

When the case 2 is attached to the heat dissipation base 5, the lower housing 3 and the upper housing 4 house therein the plurality of semiconductor units, the plurality of control wiring units, the bonding wires, and the lead frames 6, 7, and 8. The case 2 may be made of a thermoplastic resin. An example of such a resin is a polyphenylene sulfide (PPS) resin.

The heat dissipation base 5 has a flat plate shape. The heat dissipation base 5 includes side portions 5a, 5b, 5c, and 5d, the upper surface 5e, and a lower surface 5f. In plan view, the upper surface 5e and the lower surface 5f are rectangular and have the same shape and the same size. The shapes of the upper surface 5e and the lower surface 5f may correspond to the shape of the upper surface 3e of the lower housing 3 included in the case 2. The sizes of the upper surface 5e and the lower surface 5f may be the same as or slightly smaller than that of the upper surface 3e of the lower housing 3.

Each of the side portions 5a, 5b, 5c, and 5d may have a flat plate shape. The side portions 5a, 5b, 5c, and 5d surround the four sides of the upper surface 5e and the lower surface 5f. The connection portion between the side portion 5a and the side portion 5c, the connection portion between the side portion 5c and the side portion 5b, the connection portion between the side portion 5b and the side portion 5d, and the connection portion between the side portion 5d and the side portion 5a correspond to the four corner portions of the heat dissipation base 5 in plan view. The four corner portions may be R-chamfered or C-chamfered. The side portions 5a, 5b, 5c, and 5d have the same height (the thickness of the heat dissipation base 5). The side portions 5a and 5b extend along the long-side direction of the upper surface 5e and the lower surface 5f. The side portions 5c and 5d extend along the short-side direction of the upper surface 5e and the lower surface 5f.

The heat dissipation base 5 is made of a metal having excellent thermal conductivity. The metal may be, for example, aluminum, copper, or an alloy containing at least one of these metals. In order to improve corrosion resistance, the surface of the heat dissipation base 5 may be plated. Examples of the plating material include nickel and an alloy containing nickel.

The semiconductor units 10a, 10b, 10c, 10d, 10e, and 10f are provided on the upper surface 5e of the heat dissipation base 5. The semiconductor units 10a, 10b, 10c, 10d, 10e, and 10f are aligned on the upper surface 5e along the side portions 5a and 5b. The semiconductor unit 10a includes a first terminal region Ta1, a second terminal region Ta2, and a third terminal region Ta3 on the upper surface thereof. Similarly, the semiconductor unit 10b includes a first terminal region Tb1, a second terminal region Tb2, and a third terminal region Tb3 on the upper surface thereof. Similarly, the semiconductor unit 10c includes a first terminal region Tc1, a second terminal region Tc2, and a third terminal region Tc3 on the upper surface thereof. Similarly, the semiconductor unit 10d includes a first terminal region Td1, a second terminal region Td2, and a third terminal region Td3 on the upper surface thereof. Similarly, the semiconductor unit 10e includes a first terminal region Te1, a second terminal region Te2, and a third terminal region Te3 on the upper surface thereof. Similarly, the semiconductor unit 10f includes a first terminal region Tf1, a second terminal region Tf2, and a third terminal region Tf3 on the upper surface thereof. The lead frame 6, which will be described later, is bonded to the first terminal regions Ta1, Tb1, Tc1, Td1, Te1, and Tf1. The lead frame 7, which will be described later, is bonded to the second terminal regions Ta2, Tb2, Tc2, Td2, Te2, and Tf2. The lead frame 8, which will be described later, is bonded to the third terminal regions Ta3, Tb3, Tc3, Td3, Te3, and Tf3. The above bonding may be performed by, for example, ultrasonic bonding or laser welding.

The semiconductor units 10a, 10b, 10c, 10d, 10e, and 10f have the same configuration. Details of the semiconductor units 10a, 10b, 10c, 10d, 10e, and 10f will be described later.

The control wiring units 20a, 20b, 20c, and 20d are provided on the upper surface 5e of the heat dissipation base 5. The control wiring unit 20a is provided between the semiconductor unit 10a and the side portion 5a on the upper surface 5e. The control wiring unit 20b is provided between the semiconductor unit 10c and the side portion 5a on the upper surface 5e. The control wiring unit 20c is provided between the semiconductor unit 10a and the side portion 5b on the upper surface 5e. The control wiring unit 20d is provided between the semiconductor unit 10b and the side portion 5b on the upper surface 5e.

The control wiring units 20a, 20b, 20c, and 20d basically have the same configuration. As an example, the control wiring unit 20a will be described. The control wiring unit 20a includes an insulating plate 21a, conductive circuit patterns 22a and 23a, and the terminal portions 24a and 25a for control.

The insulating plate 21a is made of a ceramic material having good thermal conductivity. Such a ceramic material contains, for example, aluminum oxide, aluminum nitride, or silicon nitride as its main component.

The conductive circuit patterns 22a and 23a are made of a metal having excellent electrical conductivity. Such a metal is, for example, silver, copper, nickel, or an alloy containing at least one of these metals. In order to improve corrosion resistance, the surfaces of the conductive circuit patterns 22a and 23a may be plated. Examples of the plating material include nickel and an alloy containing nickel. The control wiring unit 20d includes one conductive circuit pattern. The size of the insulating plate of the control wiring unit 20d may correspond to the one conductive circuit pattern.

The terminal portions 24a and 25a are made of a metal having excellent electrical conductivity. Such a metal is, for example, silver, copper, nickel, or an alloy containing at least one of these metals. In order to improve corrosion resistance, the surfaces of the terminal portions 24a and 25a may be plated. Examples of the plating material include nickel and an alloy containing nickel. The lower end portion of the terminal portion 24a is bonded to the conductive circuit pattern 22a. The lower end portion of the terminal portion 25a is bonded to the conductive circuit patterns 23a. The bonding may be performed by, for example, ultrasonic bonding or laser welding. Alternatively, they may be bonded using solder or a metal sintered material. As the solder, lead-free solder is used. The lead-free solder contains, for example, an alloy containing at least two of tin, silver, copper, zinc, antimony, indium, and bismuth as its main component. The sintered material used in the metal sintered body is, for example, powder of silver, iron, copper, aluminum, titanium, nickel, tungsten, molybdenum, or an alloy containing any of these.

As with the control wiring unit 20a, the control wiring unit 20b includes the terminal portions 24b and 25b. As with the control wiring unit 20a, the control wiring unit 20c includes the terminal portions 24c and 25c. As with the terminal portion 24a of the control wiring unit 20a, the control wiring unit 20d includes the terminal portion 24d.

The control wiring units 20a and 20c are electrically connected to a plurality of semiconductor units. For example, in the case where the control wiring units 20a and 20c are connected to the semiconductor unit 10a, the terminal portion 24a of the control wiring unit 20a is connected to a fourth conductive circuit pattern 13d, which will be described later, of the semiconductor unit 10a by a bonding wire (not illustrated). The terminal portion 25a of the control wiring unit 20a is connected to a sixth conductive circuit pattern 13f, which will be described later, of the semiconductor unit 10a by a bonding wire (not illustrated). The terminal portion 24c of the control wiring unit 20c is connected to a fifth conductive circuit pattern 13e, which will be described later, of the semiconductor unit 10a by a bonding wire (not illustrated). The terminal portion 25c of the control wiring unit 20c is connected to a seventh conductive circuit pattern 13g, which will be described later, of the semiconductor unit 10a by a bonding wire (not illustrated).

The control wiring unit 20d is electrically connected to a semiconductor unit to which the control wiring units 20a and 20c are not connected among the plurality of semiconductor units. For example, in the case where the control wiring units 20a and 20c are connected to the semiconductor unit 10a, the terminal portion 24d of the control wiring unit 20d is connected to a second conductive circuit pattern 13b, which will be described later, of the semiconductor unit 10b by a bonding wire (not illustrated).

The lead frames 6, 7, and 8 are made of a metal having excellent electrical conductivity. Such a metal is, for example, silver, copper, nickel, or an alloy containing at least one of these metals. In order to improve corrosion resistance, the surfaces of the lead frames 6, 7, and 8 may be plated. Examples of the plating material include nickel and an alloy containing nickel.

The lead frame 6 integrally includes a wiring portion 6a, the terminal portion 6b, and leg portions 6c1, 6c2, 6c3, 6c4, 6c5, and 6c6. The wiring portion 6a is disposed above the semiconductor units 10a, 10b, 10c, 10d, 10e, and 10f along the side portions 5a and 5b. The terminal portion 6b is integrally connected to the upper surface of the wiring portion 6a. The leg portions 6c1, 6c2, 6c3, 6c4, 6c5, and 6c6 are integrally connected to a side portion of the wiring portion 6a. The leg portions 6c1, 6c2, 6c3, 6c4, 6c5, and 6c6 are bonded to the first terminal regions Ta1, Tb1, Tc1, Td1, Te1, and Tf1, respectively.

The lead frame 7 integrally includes a wiring portion 7a, the terminal portions 7b1 and 7b2, and leg portions 7c1, 7c2, 7c3, 7c4, 7c5, and 7c6. The wiring portion 7a is disposed above the semiconductor units 10a, 10b, 10c, 10d, 10e, and 10f along the side portions 5a and 5b. The terminal portions 7b1 and 7b2 are integrally connected to the upper surface of the wiring portion 7a. The leg portions 7c1, 7c2, 7c3, 7c4, 7c5, and 7c6 are integrally connected to a side portion of the wiring portion 7a. The leg portions 7c1, 7c2, 7c3, 7c4, 7c5, and 7c6 are bonded to the second terminal regions Ta2, Tb2, Tc2, Td2, Te2, and Tf2, respectively.

The lead frame 8 integrally includes a wiring portion 8a, the terminal portions 8b1 and 8b2, and leg portions 8c1, 8c2, 8c3, 8c4, 8c5, and 8c6. The wiring portion 8a is disposed above the semiconductor units 10a, 10b, 10c, 10d, 10e, and 10f along the side portions 5a and 5b. The wiring portion 8a is disposed with a slight gap from the wiring portion 7a. The terminal portions 8b1 and 8b2 are integrally connected to the upper surface of the wiring portion 8a. The leg portions 8c1, 8c2, 8c3, 8c4, 8c5, and 8c6 are integrally connected to a side portion of the wiring portion 8a. The leg portions 8c1, 8c2, 8c3, 8c4, 8c5, and 8c6 are bonded to the third terminal regions Ta3, Tb3, Tc3, Td3, Te3, and Tf3, respectively.

In order to improve the heat dissipation of the semiconductor device 1, a cooler (not illustrated) may be attached to the lower surface 5f of the heat dissipation base 5 of the semiconductor device 1 via thermal grease. An example of the thermal grease is silicone mixed with a metal oxide filler. Examples of the cooler include a heat sink and a cooling device. The heat sink may be provided with a plurality of fins. A plurality of fins may be directly formed on the lower surface 5f of the heat dissipation base 5. The heat sink may be made of, for example, aluminum, iron, silver, copper, or an alloy containing at least one of these, which have excellent thermal conductivity. The cooling device has a coolant that circulates inside the cooling device. The cooling device is able to cool the semiconductor device 1.

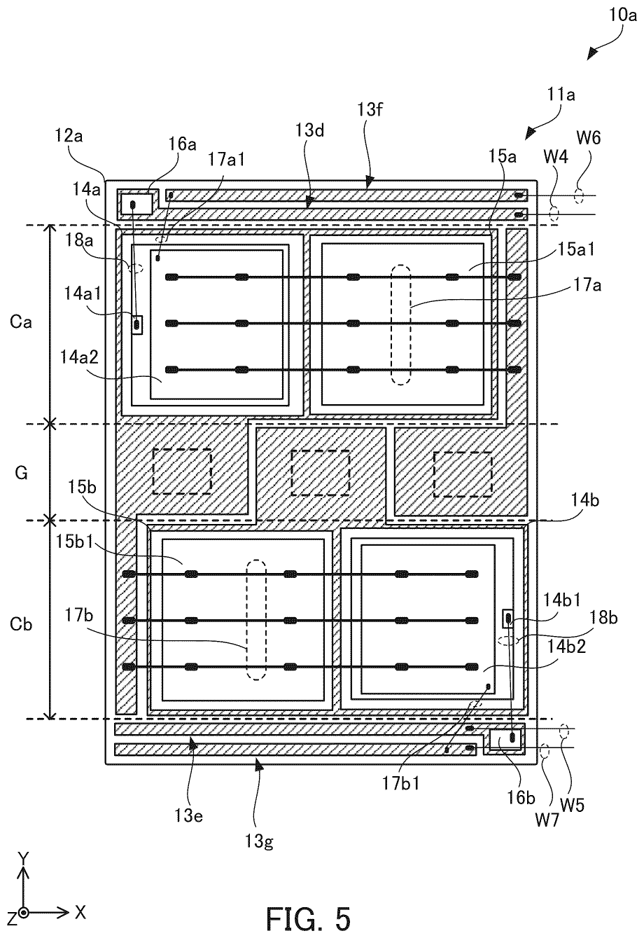

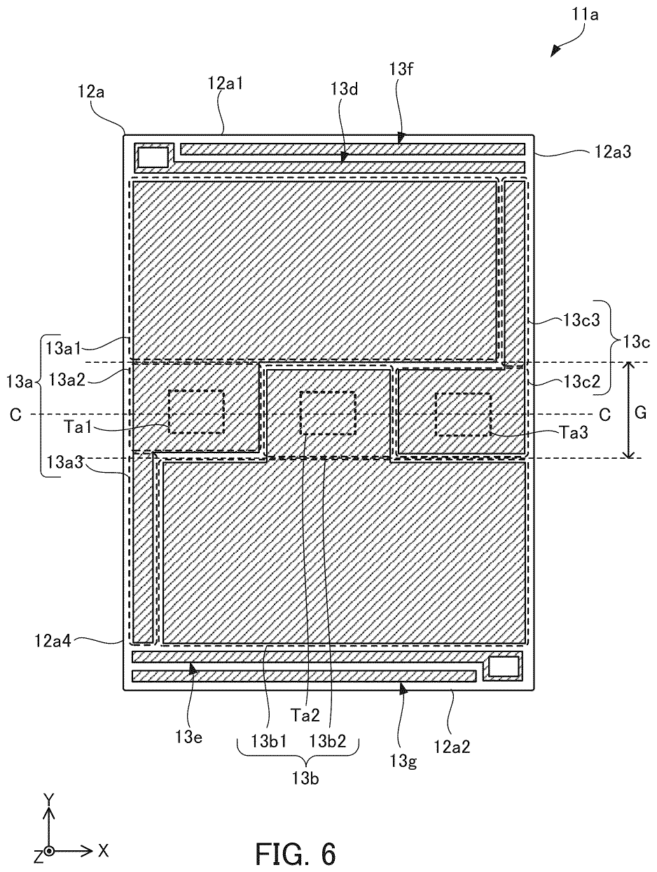

The semiconductor units 10a, 10b, 10c, 10d, 10e, and 10f will be described. The semiconductor units 10a, 10b, 10c, 10d, 10e, and 10f may have the same configuration. Hereinafter, the semiconductor unit 10a will be described with reference to FIGS. 5 and 6. FIG. 5 is a plan view of the semiconductor unit included in the semiconductor device according to the first embodiment. FIG. 6 is a plan view of an insulated circuit substrate of the semiconductor unit included in the semiconductor device according to the first embodiment.

The semiconductor unit 10a includes an insulated circuit substrate 11a, a semiconductor chip 14a and a semiconductor chip 15a (first semiconductor chip), and a semiconductor chip 14b and a semiconductor chip 15b (second semiconductor chip). The semiconductor unit 10a further includes resistive elements 16a and 16b, bonding wires 17a and 17b for main current, and bonding wires 18a and 18b for control. The semiconductor unit 10a may further include bonding wires 17a1 and 17b1 for emitter sensing.

The insulated circuit substrate 11a includes an insulating plate 12a, a metal plate (not illustrated), and a plurality of conductive circuit patterns. The insulating plate 12a has a flat plate shape and a rectangular shape in plan view. In plan view, a first side 12a1, a second side 12a2, a third side 12a3, and a fourth side 12a4 surround the four sides of the insulating plate 12a. The first side 12a1 and the second side 12a2 extend along the short-side direction of the insulating plate 12a. The third side 12a3 and the fourth side 12a4 extend along the long-side direction of the insulating plate 12a. The insulating plate 12a, as well as the insulating plates 21a, 21b, 21c, and 21d of the control wiring units 20a, 20b, 20c, and 20d, may be made of a ceramic material having good thermal conductivity. The insulating plate 12a may be made of a resin. The resin may have low thermal resistance and high insulating properties. Examples of such a resin include a thermosetting resin and a thermoplastic resin. An example of the thermosetting resin is an epoxy resin. An example of the thermoplastic resin is a polyimide resin. The resin may further contain a filler. The content and material of the filler are selected so as not to increase the thermal resistance of the insulating plate 12a. The filler may be made of at least one of an oxide and a nitride. Examples of the oxide include silicon oxide and aluminum oxide. Examples of the nitride include silicon nitride, aluminum nitride, and boron nitride.

The metal plate is smaller in area than the insulating plate 12a, and has a rectangular shape as with the insulating plate 12a. Further, the corner portions of the metal plate may be R-chamfered or C-chamfered. The metal plate is formed on the entire rear surface of the insulating plate 12a except the edge portion thereof. The metal plate is made mainly of a metal having excellent thermal conductivity. The metal may be, for example, copper, aluminum, or an alloy containing at least one of these metals. In order to improve the corrosion resistance, the surface of the metal plate may be plated. Examples of the plating material include nickel and an alloy containing nickel.

The plurality of conductive circuit patterns are made mainly of a metal having excellent electrical conductivity. Such a metal contains, for example, copper, aluminum, or an alloy containing at least one of them as its main component. In order to improve the corrosion resistance, the surfaces of the plurality of conductive circuit patterns may be plated. Examples of the plating material include nickel and an alloy containing nickel. The number of conductive circuit patterns, and the shapes and sizes of the conductive circuit patterns may be appropriately selected according to the design of the semiconductor device 1.

The plurality of conductive circuit patterns include a first conductive circuit pattern 13a, a second conductive circuit pattern 13b, and a third conductive circuit pattern 13c. The plurality of conductive circuit patterns may further include a fourth conductive circuit pattern 13d, a fifth conductive circuit pattern 13e, a sixth conductive circuit pattern 13f, and a seventh conductive circuit pattern 13g.

The first conductive circuit pattern 13a includes a first mounting portion 13a1, a first terminal portion 13a2, and a first wiring portion 13a3. On the side of the first conductive circuit pattern 13a facing the fourth side 12a4, the first mounting portion 13a1, the first terminal portion 13a2, and the first wiring portion 13a3 are aligned.

The first mounting portion 13a1 has a rectangular shape in plan view. The first mounting portion 13a1 is located on the upper surface of the insulating plate 12a, close to the first side 12a1. The first mounting portion 13a1 is disposed apart from the first side 12a1 and the third side 12a3, and along the fourth side 12a4. The semiconductor chip 14a and the semiconductor chip 15a are mounted on the first mounting portion 13a1 via a bonding material (not illustrated). The bonding material may be, for example, the above-described solder or metal sintered material.

The first terminal portion 13a2 is formed on the side of the first mounting portion 13a1 where the second side 12a2 of the insulating plate 12a is located. The first terminal portion 13a2 is located close to the fourth side 12a4 of the insulating plate 12a. The first terminal portion 13a2 may be disposed on a center line C parallel to the first side 12a1 and the second side 12a2 of the insulating plate 12a. The first terminal portion 13a2 is disposed in a gap G that will be described later. The gap G extends in parallel to the first side 12a1 and the second side 12a2 on the upper surface of the insulating plate 12a and passes through the center of the upper surface of the insulating plate 12a. The center line C passes through the center of the gap G with respect to the Y direction. The first terminal portion 13a2 includes the first terminal region Ta1. The leg portion 6c1 of the lead frame 6 (output terminal) is bonded to the first terminal region Ta1.

Likewise, the first terminal portions of the first conductive circuit patterns included in the semiconductor units 10b, 10c, 10d, 10e, and 10f include the first terminal regions Tb1, Tc1, Td1, Te1, and Tf1, respectively.

The first wiring portion 13a3 is formed on the side of the first terminal portion 13a2 where the second side 12a2 of the insulating plate 12a is located. The first wiring portion 13a3 is located close to the fourth side 12a4 of the insulating plate 12a. The first wiring portion 13a3 extends from the first terminal portion 13a2 toward the second side 12a2 along the fourth side 12a4. The first wiring portion 13a3 is disposed at the side of a second mounting portion 13b1 of the second conductive circuit pattern 13b where the fourth side 12a4 is located.

The second conductive circuit pattern 13b includes the second mounting portion 13b1 and a second terminal portion 13b2. The second mounting portion 13b1 has a rectangular shape in plan view. The second mounting portion 13b1 is disposed on the upper surface of the insulating plate 12a, close to the second side 12a2 with the gap G from the first mounting portion 13a1. The second mounting portion 13b1 and the first mounting portion 13a1 face each other while being displaced from each other in parallel to the center line C. The second mounting portion 13b1 is disposed apart from the second side 12a2 and the fourth side 12a4, and along the third side 12a3. The semiconductor chip 14b and the semiconductor chip 15b are mounted on the second mounting portion 13b1 via the above-described bonding material (not illustrated).

The second terminal portion 13b2 is formed substantially at the center on the side of the second mounting portion 13b1 where the first side 12a1 is located. The second terminal portion 13b2 may be disposed on the center line C on the upper surface of the insulating plate 12a. The second terminal portion 13b2 is located adjacent to the first terminal portion 13a2. The second terminal portion 13b2 includes the second terminal region Ta2. The leg portion 7c1 of the lead frame 7 (positive terminal) is bonded to the second terminal region Ta2.

Likewise, the second terminal portions of the second conductive circuit patterns included in the semiconductor units 10b, 10c, 10d, 10e, and 10f include the second terminal regions Tb2, Tc2, Td2, Te2, and Tf2, respectively.

The third conductive circuit pattern 13c includes a third terminal portion 13c2 and a third wiring portion 13c3. On the side of the third conductive circuit pattern 13c where the third side 12a3 is located, the third terminal portion 13c2 and the third wiring portion 13c3 are aligned.

The third terminal portion 13c2 may be disposed on the center line C on the upper surface of the insulating plate 12a. The third terminal portion 13c2 is disposed close to the third side 12a3 of the insulating plate 12a. The third terminal portion 13c2 is located adjacent to the second terminal portion 13b2. Therefore, the first terminal portion 13a2, the second terminal portion 13b2, and the third terminal portion 13c2 are aligned along the first side 12a1 and the second side 12a2 (center line C) in the gap G between the first mounting portion 13a1 and the second mounting portion 13b1 on the upper surface of the insulating plate 12a. The third terminal portion 13c2 includes the third terminal region Ta3. The leg portion 8c1 of the lead frame 8 (negative terminal) is bonded to the third terminal region Ta3.

Likewise, the third terminal portions of the third conductive circuit patterns included in the semiconductor units 10b, 10c, 10d, 10e, and 10f include the third terminal regions Tb3, Tc3, Td3, Te3, and Tf3, respectively.

The third wiring portion 13c3 is formed on the side of the third terminal portion 13c2 where the first side 12a1 is located, and is disposed close to the third side 12a3. The third wiring portion 13c3 extends from the third terminal portion 13c2 toward the first side 12a1 along the third side 12a3. The third wiring portion 13c3 is disposed at the side of the first mounting portion 13a1 of the first conductive circuit pattern 13a where the third side 12a3 is located.

The fourth conductive circuit pattern 13d has a stripe shape in plan view. The fourth conductive circuit pattern 13d is disposed along the first side 12a1 between first mounting portion 13a1 of the first conductive circuit pattern 13a and the first side 12a1 of the insulating plate 12a. The fourth conductive circuit pattern 13d extends from the third side 12a3 toward the fourth side 12a4. The end portion of the fourth conductive circuit pattern 13d located close to the fourth side 12a4 may be longer in width (in the long-side direction of the insulating plate 12a) than the remaining portion thereof. That end portion of the fourth conductive circuit pattern 13d protrudes toward the first side 12a1. The end portion is a connection portion to which the bonding wire 18a, which will be described later, is connected.

The fifth conductive circuit pattern 13e has a stripe shape in plan view. The fifth conductive circuit pattern 13e is disposed along the second side 12a2 between the second mounting portion 13b1 of the second conductive circuit pattern 13b and the second side 12a2 of the insulating plate 12a. The fifth conductive circuit pattern 13e extends from the fourth side 12a4 toward the third side 12a3. The end portion of the fifth conductive circuit pattern 13e located close to the third side 12a3 may be longer in width (in the long-side direction of the insulating plate 12a) than the remaining portion thereof. That end portion of the fifth conductive circuit pattern 13e protrudes toward the second side 12a2. The end portion is a connection portion to which the bonding wire 18b, which will be described later, is connected.

The sixth conductive circuit pattern 13f has a stripe shape in plan view. The sixth conductive circuit pattern 13f is disposed along the first side 12a1 between the fourth conductive circuit pattern 13d and the first side 12a1 of the insulating plate 12a. The sixth conductive circuit pattern 13f extends from the third side 12a3 toward the connection portion of the fourth conductive circuit pattern 13d.

The seventh conductive circuit pattern 13g has a stripe shape in plan view. The seventh conductive circuit pattern 13g is disposed along the second side 12a2 between the fifth conductive circuit pattern 13e and the second side 12a2 of the insulating plate 12a. The seventh conductive circuit pattern 13g extends from the fourth side 12a4 toward the connection portion of the fifth conductive circuit pattern 13e.

As the insulated circuit substrate 11a having such a configuration, for example, a direct copper bonding (DCB) substrate, an active metal brazed (AMB) substrate, or a resin insulating substrate may be used.

The semiconductor chips 14a and 14b each include a switching element. As an example, the switching element includes an insulated gate bipolar transistor (IGBT). The semiconductor material forming the semiconductor chips 14a and 14b is silicon, for example. Input electrodes (collector electrodes) serving as main electrodes are provided on the lower surfaces of the semiconductor chips 14a and 14b. Control electrodes 14a1 and 14b1 (gate electrodes) and output electrodes 14a2 and 14b2 (emitter electrodes) serving as main electrodes are provided on the upper surfaces of the semiconductor chips 14a and 14b, respectively. The semiconductor chips 14a and 14b have a rectangular shape in plan view. Each of the control electrodes 14a1 and 14b1 may be provided on one side of the upper surface of the corresponding semiconductor chip 14a or 14b. In the present embodiment, each of the control electrodes 14a1 and 14b1 is provided at the center on one side of the upper surface of the corresponding semiconductor chip 14a or 14b.

The semiconductor chip 14a is mounted in the first mounting portion 13a1 of the first conductive circuit pattern 13a, close to the fourth side 12a4. Further, the control electrode 14a1 of the semiconductor chip 14a faces the fourth side 12a4.

The semiconductor chip 14b is mounted in the second mounting portion 13b1 of the second conductive circuit pattern 13b, close to the third side 12a3. Further, the control electrode 14b1 of the semiconductor chip 14b faces the third side 12a3.

The semiconductor chips 15a and 15b each include a diode element. As an example, the diode element may be a free wheeling diode (FWD). For example, a Schottky barrier diode (SBD) or a P-intrinsic-N (PiN) diode may be used as the FWD. The semiconductor material forming the semiconductor chips 15a and 15b is silicon, for example. Output electrodes (cathode electrodes) (not illustrated) are provided on the lower surfaces of the semiconductor chips 15a and 15b. Input electrodes 15a1 and 15b1 (anode electrodes) are provided on the upper surfaces of the semiconductor chips 15a and 15b. The semiconductor chips 15a and 15b have a rectangular shape in plan view.

The semiconductor chip 15a is mounted in the first mounting portion 13a1 of the first conductive circuit pattern 13a, close to the third side 12a3. That is, the semiconductor chip 15a is mounted adjacent to the semiconductor chip 14a, in the first mounting portion 13a1.

The semiconductor chip 15b is mounted in the second mounting portion 13b1 of the second conductive circuit pattern 13b, close to the fourth side 12a4. That is, the semiconductor chip 15b is mounted adjacent to the semiconductor chip 14b, in the second mounting portion 13b1.

The semiconductor chip 14a and the semiconductor chip 15a, and the semiconductor chip 14b and the semiconductor chip 15b are arranged on the insulated circuit substrate 11a so as to be substantially point-symmetrical with respect to the center of the insulated circuit substrate 11a.

The bonding wires 17a and 17b are examples of first and second main wiring members. The first and second main wiring members may be ribbons. The bonding wires 17a electrically connect the output electrode 14a2 of the semiconductor chip 14a, the input electrode 15a1 of the semiconductor chip 15a, and the third wiring portion 13c3 of the third conductive circuit pattern 13c. The bonding wires 17a extend along the first side 12a1 and the second side 12a2.

The bonding wires 17b electrically connect the output electrode 14b2 of the semiconductor chip 14b, the input electrode 15b1 of the semiconductor chip 15b, and the first wiring portion 13a3 of the first conductive circuit pattern 13a. The bonding wires 17b extend along the first side 12a1 and the second side 12a2.

The bonding wire 18a electrically connects the control electrode 14a1 of the semiconductor chip 14a to the fourth conductive circuit pattern 13d. The bonding wire 18a is connected to the end portion of the fourth conductive circuit pattern 13d located close to the fourth side 12a4. The wiring direction of the bonding wire 18a may be substantially parallel to the third side 12a3 and the fourth side 12a4. The bonding wire 18a may be connected to the fourth conductive circuit pattern 13d via the resistive element 16a. The end portion of the fourth conductive circuit pattern 13d where the resistive element 16a is provided may be longer in width (in the long-side direction of the insulating plate 12a) than the remaining portion thereof.

The bonding wire 18b electrically connects the control electrode 14b1 of the semiconductor chip 14b to the fifth conductive circuit pattern 13e. The bonding wire 18b is connected to the end portion of the fifth conductive circuit pattern 13e located close to the third side 12a3. The wiring direction of the bonding wire 18b may be substantially parallel to the third side 12a3 and the fourth side 12a4. The bonding wire 18b may be connected to the fifth conductive circuit pattern 13e via the resistive element 16b. The end portion of the fifth conductive circuit pattern 13e where the resistive element 16b is provided may be longer in width (in the long-side direction of the insulating plate 12a) than the remaining portion thereof.

The bonding wire 17a1 electrically connects the output electrode 14a2 of the semiconductor chip 14a and the sixth conductive circuit pattern 13f. The bonding wire 17a1 is connected to the end portion of the sixth conductive circuit pattern 13f located close to the fourth side 12a4. The bonding wire 17b1 electrically connects the output electrode 14b2 of the semiconductor chip 14b to the seventh conductive circuit pattern 13g. The bonding wire 17b1 is connected to the end portion of seventh conductive circuit pattern 13g located close to the third side 12a3.

The bonding wires 17a and 17b, the bonding wires 18a and 18b, and the bonding wires 17a1 and 17b1 are made mainly of a material having excellent electrical conductivity. Examples of such a material include gold, copper, aluminum, and an alloy containing at least one of these metals. The diameters of the bonding wires 17a and 17b and the bonding wires 17a1 and 17b1 are larger than those of the bonding wires 18a and 18b.

The semiconductor unit 10a has the above-described configuration. The semiconductor units 10b, 10c, 10d, 10e, and 10f may also have the same configuration as the semiconductor unit 10a described above. The semiconductor units 10a, 10b, 10c, 10d, 10e, and 10f are bonded to the heat dissipation base 5 via a bonding material (not illustrated). The bonding material may be a brazing material or a thermal interface material. The brazing material contains, for example, at least one of an aluminum alloy, a titanium alloy, a magnesium alloy, a zirconium alloy, and a silicon alloy as its main component. Examples of the thermal interface material include various materials such as thermally conductive grease, elastomer sheet, room temperature vulcanization (RTV) rubber, gel, and phase change material.

Each fourth conductive circuit pattern included in the plurality of semiconductor units is bonded via a bonding wire to another fourth conductive circuit pattern adjacent to it. Each fifth conductive circuit pattern included in the plurality of semiconductor units is bonded via a bonding wire to another fifth conductive circuit pattern that is adjacent to it.

Each sixth conductive circuit pattern included in the plurality of semiconductor units is bonded via a bonding wire to another sixth conductive circuit pattern that is adjacent to it. Each seventh conductive circuit pattern included in the plurality of semiconductor units is bonded via a bonding wire to another seventh conductive circuit pattern that is adjacent to it.

As a specific example, as illustrated in FIG. 5, a bonding wire W4 connects the fourth conductive circuit pattern 13d of the semiconductor unit 10a to the fourth conductive circuit pattern of the semiconductor unit 10b (not illustrated) adjacent to the semiconductor unit 10a. Similarly, a bonding wire W5 connects the fifth conductive circuit pattern 13e of the semiconductor unit 10a to the fifth conductive circuit pattern of the semiconductor unit 10b (not illustrated).

Similarly, a bonding wire W6 connects the sixth conductive circuit pattern 13f of the semiconductor unit 10a to the sixth conductive circuit pattern of the semiconductor unit 10b (not illustrated). Similarly, a bonding wire W7 connects the seventh conductive circuit pattern 13g of the semiconductor unit 10a to the seventh conductive circuit pattern of the semiconductor unit 10b (not illustrated).

Here, another semiconductor unit will be described. The same reference numerals are used to denote the same components included in the other semiconductor unit as those included in the semiconductor unit 10a, and a detailed description thereof may be omitted.

The other semiconductor unit similarly includes an insulated circuit substrate, a semiconductor chip 14a, a semiconductor chip 15a, a semiconductor chip 14b, and a semiconductor chip 15b. The other semiconductor unit further includes resistive elements 16a and 16b, bonding wires for main current, bonding wires for control, and bonding wires for emitter sensing.

The insulated circuit substrate includes an insulating plate 12a, a metal plate, and a plurality of conductive circuit patterns. The insulating plate 12a is as described in the first embodiment. The plurality of conductive circuit patterns include a positive conductive circuit pattern, an output conductive circuit pattern, a negative conductive circuit pattern, and control conductive circuit patterns.

The semiconductor chip 14a and the semiconductor chip 15a are mounted on the positive conductive circuit pattern. The positive conductive circuit pattern is provided close to a fourth side 12a4 of the insulating plate 12a along the fourth side 12a4. The positive conductive circuit pattern includes a positive terminal region on the side thereof close to the second side 12a2. A lead frame 7 serving as a positive terminal is electrically connected to the positive terminal region. The semiconductor chip 14a and the semiconductor chip 15a are mounted in a region of the positive conductive circuit pattern corresponding to the center of the insulating plate 12a.

The semiconductor chip 14b and the semiconductor chip 15b are mounted on the output conductive circuit pattern. The output conductive circuit pattern is provided close to the third side 12a3 of the insulating plate 12a and adjacent to the positive conductive circuit pattern. That is, the output conductive circuit pattern faces the sides of the positive conductive circuit pattern where the first side 12a1 and the third side 12a3 are located. The output conductive circuit pattern includes an output terminal region on the side thereof close to the first side 12a1. A lead frame 6 serving as an output terminal is electrically connected to the output terminal region. The semiconductor chip 14b and the semiconductor chip 15b are mounted in a region of the output conductive circuit pattern corresponding to the center of the insulating plate 12a.

The negative conductive circuit pattern is provided in a region surrounded by the side of the positive conductive circuit pattern facing the third side 12a3, the side of the output conductive circuit pattern facing the second side 12a2, and the third side 12a3. The negative conductive circuit pattern includes a negative terminal region. A lead frame 8 serving as a negative terminal is electrically connected to the negative terminal region.

One control conductive circuit pattern is provided closer to the first side 12a1 than is the output conductive circuit pattern. The other control conductive circuit pattern is provided closer to the second side 12a2 than are the two positive and negative conductive circuit patterns.

In above-described other semiconductor unit, the semiconductor chip 14a and the semiconductor chip 15a, and the semiconductor chip 14b and the semiconductor chip 15b are arranged in the central region of the insulating plate 12a with respect to the long-side direction. The output terminal region of the output conductive circuit pattern is provided closer to the first side 12a1 than is the central region. The positive terminal region of the positive conductive circuit pattern and the negative terminal region of the negative conductive circuit pattern are provided closer to the second side 12a2 than is the central region. Therefore, the central region is sandwiched by the output terminal region of the output conductive circuit pattern, and the positive terminal region of the positive conductive circuit pattern and the negative terminal region of the negative conductive circuit pattern.

In the other semiconductor unit, the lead frame 6 is bonded to the output terminal region. Therefore, the area in the vicinity of the output terminal region of the output conductive circuit pattern needs to have large space enough to place a tool for bonding the lead frame 6. Similarly, the area in the vicinity of the positive terminal region of the positive conductive circuit pattern and the area in the vicinity of the negative terminal region of the negative conductive circuit pattern also need to have large space enough to place a tool for bonding the lead frames 7 and 8.

As described above, since some space is needed in the vicinity of each of the output terminal region, the positive terminal region, and the negative terminal region, the size of the central region in which the semiconductor chip 14a and the semiconductor chip 15a, and the semiconductor chip 14b and the semiconductor chip 15b are arranged is limited. In this case, the semiconductor chip 14a and the semiconductor chip 15a, and the semiconductor chip 14b and the semiconductor chip 15b, which are mounted in the central region, are densely arranged. As a result, heat generated by the semiconductor chip 14a and the semiconductor chip 15a and heat generated by the semiconductor chip 14b and the semiconductor chip 15b interfere with each other. Such thermal interference may increase the temperature of the central region. If the temperature becomes high, the properties and lifetime of the semiconductor chip 14a and the semiconductor chip 15a and the semiconductor chip 14b and the semiconductor chip 15b may be degraded.

Furthermore, in the other semiconductor unit, the positive conductive circuit pattern, the negative conductive circuit pattern, and the output conductive circuit pattern are formed on the insulating plate 12a. In addition, the control conductive circuit patterns need to be formed in vacant regions of the insulating plate 12a. Therefore, the shapes of these various conductive circuit patterns may become complicated.

By contrast, in the semiconductor device 1, the insulated circuit substrate 11a included in the semiconductor unit 10a includes the insulating plate 12a, the first conductive circuit pattern 13a, the second conductive circuit pattern 13b, and the third conductive circuit pattern 13c. The insulating plate 12a has the first side 12a1 and the second side 12a2 opposite to each other in plan view. The first conductive circuit pattern 13a, the second conductive circuit pattern 13b, and the third conductive circuit pattern 13c are formed on the upper surface of the insulating plate 12a.

The first conductive circuit pattern 13a includes the first mounting portion 13a1 and the first terminal portion 13a2. The lower surface of the semiconductor chip 14a and the lower surface of the semiconductor chip 15a are mounted on the first mounting portion 13a1. The lead frame 6 is bonded to the first terminal portion 13a2. The second conductive circuit pattern 13b includes the second mounting portion 13b1 and the second terminal portion 13b2. The lower surface of the semiconductor chip 14b and the lower surface of the semiconductor chip 15b are mounted on the second mounting portion 13b1. The lead frame 7 is bonded to the second terminal portion 13b2. The third conductive circuit pattern 13c includes the third terminal portion 13c2. The lead frame 8 is bonded to the third terminal portion 13c2.

Further, the first mounting portion 13a1 of the first conductive circuit pattern 13a is located on the upper surface of the insulating plate 12a, close to the first side 12a1. The second mounting portion 13b1 of the second conductive circuit pattern 13b is located on the upper surface of insulating plate 12a, close to the second side 12a2, and has the gap G from the first mounting portion 13a1. The first terminal portion 13a2, the second terminal portion 13b2, and the third terminal portion 13c2 are sequentially arranged along the first side 12a1 and the second side 12a2 in the gap G on the upper surface of the insulating plate 12a.

In the insulated circuit substrate 11a of the semiconductor unit 10a, the first terminal portion 13a2, the second terminal portion 13b2, and the third terminal portion 13c2 are arranged together in the gap G between the first mounting portion 13a1 and the second mounting portion 13b1. Therefore, the gap G is shared as a region for placing a tool for bonding the lead frames 6, 7, and 8. This eliminates the need to secure space for bonding each of the lead frames 6, 7, and 8, which achieves space saving in mounting the first terminal portion 13a2, the second terminal portion 13b2, and the third terminal portion 13c2. In the gap G, the first terminal portion 13a2, the second terminal portion 13b2, and the third terminal portion 13c2 are aligned along the first side 12a1 and the second side 12a2. As a result, further space saving is achieved.

By saving space in mounting the first terminal portion 13a2, the second terminal portion 13b2, and the third terminal portion 13c2, the first mounting portion 13a1 and the second mounting portion 13b1 may be enlarged. In particular, the first mounting portion 13a1 and the second mounting portion 13b1 have a rectangular shape in plan view. The first mounting portion 13a1 and the second mounting portion 13b1 having such simple shapes are disposed close to the first side 12a1 and the second side 12a2, respectively, with the gap G interposed therebetween.

In addition, the first terminal portion 13a2, the second terminal portion 13b2, and the third terminal portion 13c2 are aligned along the first side 12a1 and the second side 12a2, and the lead frames 6, 7, and 8 are provided along the first side 12a1 and the second side 12a2. In particular, the lead frame 7 for positive electrode and the lead frame 8 for negative electrode may be arranged close to each other in parallel. A current flowing through the lead frame 7 and a current flowing through the lead frame 8 have opposite directions, which reduces the occurrence of inductance.

The fourth conductive circuit pattern 13d may be disposed adjacent to the first mounting portion 13a1 of the first conductive circuit pattern 13a. Similarly, the fifth conductive circuit pattern 13e may be disposed adjacent to the second mounting portion 13b1 of the second conductive circuit pattern 13b. As a result, the wiring of the bonding wires 18a and 18b is improved. For example, the fourth conductive circuit pattern 13d and the control electrode 14a1 of the semiconductor chip 14a in the first mounting portion 13a1 are directly connected to each other with the bonding wire 18a at the shortest distance. The fifth conductive circuit pattern 13e and the control electrode 14b1 of the semiconductor chip 14b in the second mounting portion 13b1 are directly connected to each other with the bonding wire 18b at the shortest distance.

### Second Embodiment

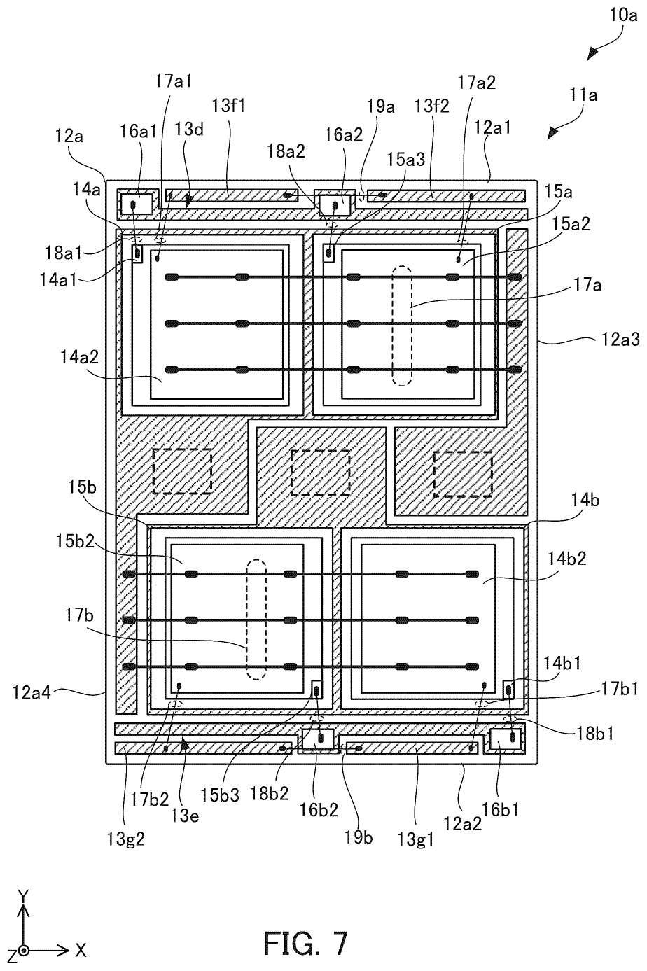

Semiconductor chips of semiconductor units included in a semiconductor device according to a second embodiment are switching elements. The following describes a case where a semiconductor material forming the switching elements is silicon and the switching elements are reverse-conducting (RC)-IGBTs, with reference to FIG. 7. A semiconductor unit of the second embodiment will be described, mainly with respect to the configuration different from that of the first embodiment. An insulating plate and first, second, and third conductive circuit patterns of an insulated circuit substrate in the second embodiment are the same as those in the first embodiment, and reference may be made to the insulated circuit substrate 11a illustrated in FIG. 5. In the second embodiment, a semiconductor unit 10a among the plurality of semiconductor units included in the semiconductor device will be described as an example.

FIG. 7 is a plan view of the semiconductor unit included in the semiconductor device according to the second embodiment. Semiconductor chips 14a and 15a and semiconductor chips 14b and 15b included in the semiconductor unit 10a of the second embodiment are, for example, RC-IGBTs. The RC-IGBT is a semiconductor element in which an IGBT and an FWD are configured in inverse-parallel in one chip.

The semiconductor chips 14a and 15a and the semiconductor chips 14b and 15b may have a rectangular shape in plan view. Input electrodes (collector electrodes) serving as main electrodes are provided on the lower surfaces of the semiconductor chips 14a and 15a and the semiconductor chips 14b and 15b. A control electrode 14a1 (gate electrode) and an output electrode 14a2 (emitter electrode) serving as a main electrode are provided on the upper surface of the semiconductor chip 14a. A control electrode 15a3 (gate electrode) and an output electrode 15a2 (emitter electrode) serving as a main electrode are provided on the upper surface of the semiconductor chip 15a. A control electrode 14b1 (gate electrode) and an output electrode 14b2 (emitter electrode) serving as a main electrode are provided on the upper surface of the semiconductor chip 14b. A control electrode 15b3 (gate electrode) and an output electrode 15b2 (emitter electrode) serving as a main electrode are provided on the upper surface of the semiconductor chip 15b.

The control electrode 14a1 may be provided on one side of the upper surface of the semiconductor chip 14a. In the present embodiment, the control electrode 14a1 is provided at an end portion on the one side of the upper surface of the semiconductor chip 14a. The semiconductor chip 14a is mounted on a first conductive circuit pattern 13a such that the control electrode 14a1 faces a first side 12a1. The control electrode 15a3 may be provided on one side of the upper surface of the semiconductor chip 15a. In the present embodiment, the control electrode 15a3 is provided at an end portion on the one side of the upper surface of the semiconductor chip 15a. The semiconductor chip 15a is mounted on the first conductive circuit pattern 13a such that the control electrode 15a3 faces the first side 12a1.

The control electrode 14b1 may be provided on one side of the upper surface of the semiconductor chip 14b. In the present embodiment, the control electrode 14b1 is provided at an end portion on the one side of the upper surface of the semiconductor chip 14b. The semiconductor chip 14b is mounted on the second conductive circuit pattern 13b such that the control electrode 14b1 faces a second side 12a2. The control electrode 15b3 may be provided on one side of the upper surface of the semiconductor chip 15b. In the present embodiment, the control electrode 15b3 is provided at an end portion on the one side of the upper surface of the semiconductor chip 15b. The semiconductor chip 15b is mounted on the second conductive circuit pattern 13b such that the control electrode 15b3 faces the second side 12a2.

An end portion of a fourth conductive circuit pattern 13d faces the control electrode 14a1 of the semiconductor chip 14a mounted on the first conductive circuit pattern 13a. The end portion protrudes toward the first side 12a1 in plan view. This end portion is a connection portion electrically connected to the control electrode 14a1 of the semiconductor chip 14a by a bonding wire 18a1. The connection portion may be connected to the bonding wire 18a1 via a resistive element 16a1.

The fourth conductive circuit pattern 13d includes a connection portion at a position facing the control electrode 15a3 of the semiconductor chip 15a mounted on the first conductive circuit pattern 13a. The connection portion also protrudes toward the first side 12a1 in plan view. This connection portion is electrically connected to the control electrode 15a3 of the semiconductor chip 15a by a bonding wire 18a2. The connection portion may be connected to the bonding wire 18a2 via a resistive element 16a2.

A sixth conductive circuit pattern 13f1 is disposed along the first side 12a1 between the two connection portions of the fourth conductive circuit pattern 13d. A sixth conductive circuit pattern 13f2 is disposed along the first side 12a1 between the connection portion (facing the control electrode 15a3) of the fourth conductive circuit pattern 13d and a third side 12a3. The sixth conductive circuit pattern 13f1 and the sixth conductive circuit pattern 13f2 are electrically connected to each other by a bonding wire 19a.

The sixth conductive circuit pattern 13f1 and the output electrode 14a2 of the semiconductor chip 14a are connected by a bonding wire 17a1. The sixth conductive circuit pattern 13f2 and the output electrode 15a2 of semiconductor chip 15a are connected by a bonding wire 17a2.

An end portion of a fifth conductive circuit pattern 13e faces the control electrode 14b1 of the semiconductor chip 14b mounted on the second conductive circuit pattern 13b. The end portion protrudes toward the second side 12a2 in plan view. This end portion is a connection portion electrically connected to the control electrode 14b1 of the semiconductor chip 14b by a bonding wire 18b1. The connection portion may be connected to the bonding wire 18b1 via a resistive element 16b1.

The fifth conductive circuit pattern 13e also includes a connection portion at a position facing the control electrode 15b3 of the semiconductor chip 15b mounted on the second conductive circuit pattern 13b. The connection portion also protrudes toward the second side 12a2 in plan view. This connection portion is electrically connected to the control electrode 15b3 of the semiconductor chip 15b by a bonding wire 18b2. The connection portion may be connected to the bonding wire 18b2 via a resistive element 16b2.

A seventh conductive circuit pattern 13g1 is disposed along the second side 12a2 between the two connection portions of the fifth conductive circuit pattern 13e. A seventh conductive circuit pattern 13g2 is disposed along the second side 12a2 between the connection portion (facing the control electrode 15b3) of the fifth conductive circuit pattern 13e and a fourth side 12a4. The seventh conductive circuit pattern 13g1 and the seventh conductive circuit pattern 13g2 are electrically connected by a bonding wire 19b.

The seventh conductive circuit pattern 13g1 and the output electrode 14b2 of the semiconductor chip 14b are connected by a bonding wire 17b1. The seventh conductive circuit pattern 13g2 and the output electrode 15b2 of the semiconductor chip 15b are connected by a bonding wire 17b2.

Bonding wires 17 a electrically connect the output electrode 14a2 of the semiconductor chip 14a, the output electrode 15a2 of the semiconductor chip 15a, and a third wiring portion 13c3 of a third conductive circuit pattern 13c. The bonding wires 17a extend along the first side 12a1 and the second side 12a2.

Bonding wires 17 b electrically connect the output electrode 14b2 of the semiconductor chip 14b, the output electrode 15b2 of the semiconductor chip 15b, and a first wiring portion 13a3 of the first conductive circuit pattern 13a. The bonding wires 17b extend along the first side 12a1 and the second side 12a2.

The bonding wires 18a1, 18a2, 18b1, and 18b2 may be made of the same material as the bonding wires described earlier. The diameters of the bonding wires 18a1, 18a2, 18b1, and 18b2 may be smaller than those of the bonding wires 17a and 17b. The wiring directions of the bonding wires 18a1, 18a2, 18b1, and 18b2 may be substantially orthogonal to the those of the bonding wires 17a and 17b.

According to the second embodiment, even in the case where the semiconductor chips 14a, 15a, 14b, and 15b are RC-IGBTs, the first mounting portion 13a1 and the second mounting portion 13b1 in the semiconductor device may be enlarged as much as possible, as in the first embodiment.

### Third Embodiment

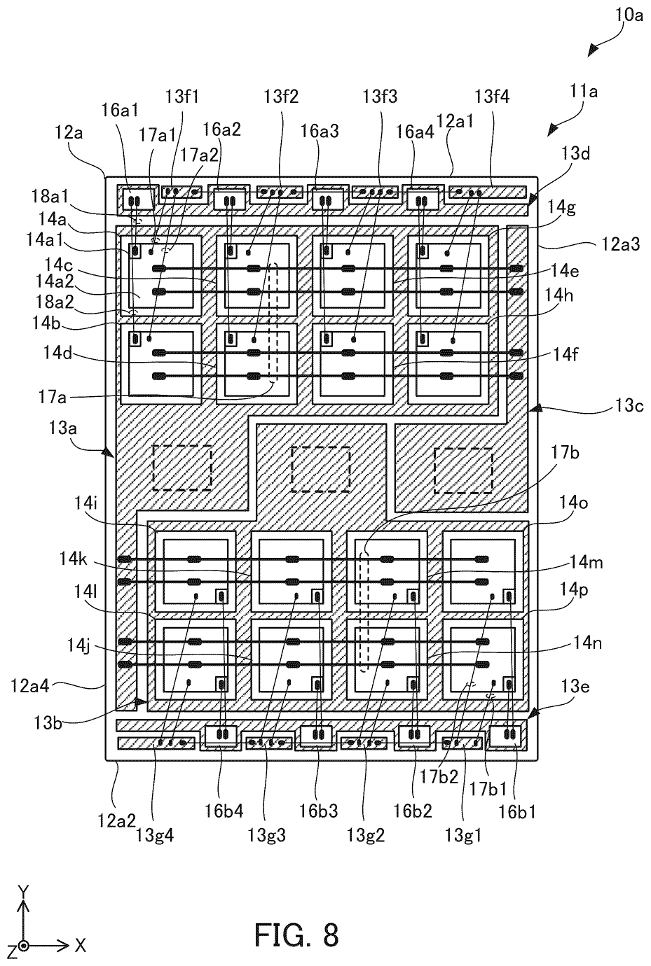

Semiconductor chips of semiconductor units included in a semiconductor device according to a third embodiment are switching elements. The following describes a case where a semiconductor material forming the switching elements is silicon carbide and the switching elements are power metal-oxide-semiconductor field-effect transistors (MOSFETs), with reference to FIG. 8. A semiconductor unit of the third embodiment will be described, mainly with respect to the configuration different from that of the first embodiment. An insulating plate, a first conductive circuit pattern, a second conductive circuit pattern, and a third conductive circuit pattern of an insulated circuit substrate in the third embodiment are the same as those in the first embodiment, and reference may be made to the insulated circuit substrate 11a illustrated in FIG. 6. Also in the third embodiment, a semiconductor unit 10a among the plurality of semiconductor units included in the semiconductor device will be described as an example.

FIG. 8 is a plan view of the semiconductor unit included in the semiconductor device according to the third embodiment. Semiconductor chips 14a, 14b, 14c, 14d, 14e, 14f, 14g, and 14h included in the semiconductor unit 10a of the third embodiment are all power MOSFETs. Semiconductor chips 14i, 14j, 14k, 14l, 14m, 14n, 14o, and 14p are also power MOSFETs.

The semiconductor chips 14a, 14c, 14e, and 14g are mounted along a first side 12a1, on the side of a first mounting portion 13a1 of a first conductive circuit pattern 13a where the first side 12a1 is located. The semiconductor chips 14b, 14d, 14f, and 14h are mounted closer to a second side 12a2 than are the semiconductor chips 14a, 14c, 14e, and 14g, respectively, in the first mounting portion 13a1 of the first conductive circuit pattern 13a.

The semiconductor chips 14l, 14j, 14n, and 14p are mounted along the second side 12a2, on the side of a second mounting portion 13b1 of a second conductive circuit pattern 13b where the second side 12a2 is located. The semiconductor chips 14i, 14k, 14m, and 14o are mounted closer to the first side 12a1 than are the semiconductor chips 14l, 14j, 14n, and 14p, respectively, in the second mounting portion 13b1 of the second conductive circuit pattern 13b.

These semiconductor chips have the same configuration. Hereinafter, the semiconductor chip 14a will be described. The semiconductor chip 14a may have a rectangular shape in plan view. An input electrode (drain electrode) serving as a main electrode is provided on the lower surface of the semiconductor chip 14a. A control electrode 14a1 (gate electrode) and an output electrode 14a2 (source electrode) serving as a main electrode are provided on the upper surface of the semiconductor chip 14a. The control electrode 14a1 may be provided on one side of the upper surface of the semiconductor chip 14a. In the present embodiment, the control electrode 14a1 is provided at an end portion on the one side of the upper surface of the semiconductor chip 14a. The semiconductor chip 14a is mounted on the first conductive circuit pattern 13a such that the control electrode 14a1 faces the first side 12a1.

The semiconductor chips 14b, 14c, 14d, 14e, 14f, 14g, and 14h are also mounted in the first mounting portion 13a1 of the first conductive circuit pattern 13a such that their control electrodes (reference numerals omitted) face the first side 12a1.

An end portion of a fourth conductive circuit pattern 13d faces the control electrode 14a1 of the semiconductor chip 14a mounted on the first conductive circuit pattern 13a. The end portion protrudes toward the first side 12a1. This end portion is a connection portion electrically connected to the control electrode 14a1 of the semiconductor chip 14a by a bonding wire 18a1. Similarly, the connection portion is electrically connected to the control electrode of the semiconductor chip 14b by a bonding wire 18a2. The connection portion may be connected to the bonding wires 18a1 and 18a2 via a resistive element 16a1.

The fourth conductive circuit pattern 13d also includes connection portions at positions facing control electrodes (reference numerals omitted) of the semiconductor chips 14c, 14e, and 14g mounted on the first conductive circuit pattern 13a. Each of these connection portions also protrudes toward the first side 12a1 in plan view. The connection portions are electrically connected to the control electrodes of the semiconductor chips 14c, 14e, and 14g by bonding wires (reference numerals omitted). The connection portions may be connected to the bonding wires via resistive elements 16a2, 16a3, and 16a4.

The control electrodes (reference numerals omitted) of the semiconductor chips 14d, 14f, and 14h mounted on the first conductive circuit pattern 13a are electrically connected to the connection portions of the fourth conductive circuit pattern 13d by bonding wires (reference numerals omitted). The connection portions may be connected to the bonding wires via the resistive elements 16a2, 16a3, and 16a4, respectively.

Sixth conductive circuit patterns 13f1, 13f2, and 13f3 are arranged along the first side 12a1 between the four connection portions of the fourth conductive circuit pattern 13d. A sixth conductive circuit pattern 13f4 is arranged along the first side 12a1 between the connection portion (facing the semiconductor chip 14g) of the fourth conductive circuit pattern 13d and a third side 12a3. The sixth conductive circuit pattern 13f1, the sixth conductive circuit pattern 13f2, the sixth conductive circuit pattern 13f3, and the sixth conductive circuit pattern 13f4 are electrically connected to each other by a bonding wire (reference numeral omitted).

The sixth conductive circuit pattern 13f1 and the output electrode 14a2 of the semiconductor chip 14a are connected by a bonding wire 17a1. The sixth conductive circuit pattern 13f1 and the output electrode 14b2 of the semiconductor chip 14b are connected by a bonding wire 17a2.

Similarly, the sixth conductive circuit pattern 13f2 and the output electrode (reference numeral omitted) of the semiconductor chip 14c are connected by a bonding wire (reference numeral omitted). The sixth conductive circuit pattern 13f2 and the output electrode (reference numeral omitted) of the semiconductor chip 14d are connected by a bonding wire (reference numeral omitted).

Similarly, the sixth conductive circuit pattern 13f3 and the output electrode (reference numeral omitted) of the semiconductor chip 14e are connected by a bonding wire (reference numeral omitted). The sixth conductive circuit pattern 13f3 and the output electrode (reference numeral omitted) of the semiconductor chip 14f are connected by a bonding wire (reference numeral omitted).

Similarly, the sixth conductive circuit pattern 13f4 and the output electrode (reference numeral omitted) of the semiconductor chip 14g are connected by a bonding wire (reference numeral omitted). The sixth conductive circuit pattern 13f4 and the output electrode (reference numeral omitted) of the semiconductor chip 14h are connected by a bonding wire (reference numeral omitted).

As with the fourth conductive circuit pattern 13d, connection portions of a fifth conductive circuit pattern 13e facing the control electrodes (reference numerals omitted) of the semiconductor chips 14l, 14j, 14n, and 14p protrude toward the second side 12a2. These connection portions are electrically connected to the control electrodes of the semiconductor chips 14l, 14j, 14n, and 14p by bonding wires (reference numerals omitted). The connection portions of the fifth conductive circuit pattern 13e may be connected to the bonding wires via resistive elements 16b1, 16b2, 16b3, and 16b4, respectively.

Seventh conductive circuit patterns 13g1, 13g2, and 13g3 are arranged along the second side 12a2 between the four connection portions of the fifth conductive circuit pattern 13e. A seventh conductive circuit pattern 13g4 is arranged along the second side 12a2 between the connection portion (facing the semiconductor chip 14l) of the fifth conductive circuit pattern 13e and a fourth side 12a4. The seventh conductive circuit pattern 13g1, the seventh conductive circuit pattern 13g2, the seventh conductive circuit pattern 13g3, and the seventh conductive circuit pattern 13g4 are electrically connected to each other by a bonding wire (reference numeral omitted).

The seventh conductive circuit pattern 13g1 and the output electrode (reference numeral omitted) of the semiconductor chip 14p are connected by a bonding wire 17b1. The seventh conductive circuit pattern 13g1 and the output electrode (reference numeral omitted) of the semiconductor chip 14o are connected by a bonding wire 17b2.

Similarly, the seventh conductive circuit pattern 13g2 and the output electrode (reference numeral omitted) of the semiconductor chip 14n are connected by a bonding wire (reference numeral omitted). The seventh conductive circuit pattern 13g2 and the output electrode (reference numeral omitted) of the semiconductor chip 14m are connected by a bonding wire (reference numeral omitted).

Similarly, the seventh conductive circuit pattern 13g3 and the output electrode (reference numeral omitted) of the semiconductor chip 14j are connected by a bonding wire (reference numeral omitted). The seventh conductive circuit pattern 13g3 and the output electrode (reference numeral omitted) of the semiconductor chip 14k are connected by a bonding wire (reference numeral omitted).

Similarly, the seventh conductive circuit pattern 13g4 and the output electrode (reference numeral omitted) of the semiconductor chip 14l are connected by a bonding wire (reference numeral omitted). The seventh conductive circuit pattern 13g4 and the output electrode (reference numeral omitted) of the semiconductor chip 14i are connected by a bonding wire (reference numeral omitted).

Bonding wires 17a electrically connect the output electrode 14a2 of the semiconductor chip 14a, the output electrode of the semiconductor chip 14c, the output electrode of the semiconductor chip 14e, the output electrode of the semiconductor chip 14g, and a third wiring portion 13c3 of a third conductive circuit pattern 13c. The bonding wires 17a electrically connect the output electrode of the semiconductor chip 14b, the output electrode of the semiconductor chip 14d, the output electrode of the semiconductor chip 14f, the output electrode of the semiconductor chip 14h, and the third wiring portion 13c3 of the third conductive circuit pattern 13c. The bonding wires 17a extend along the first side 12a1 and the second side 12a2.

Bonding wires 17b electrically connect the output electrode of the semiconductor chip 14p, the output electrode of the semiconductor chip 14n, the output electrode of the semiconductor chip 14j, the output electrode of the semiconductor chip 14l, and the first wiring portion 13a3 of the first conductive circuit pattern 13a. The bonding wires 17b electrically connect the output electrode of the semiconductor chip 14o, the output electrode of the semiconductor chip 14m, the output electrode of the semiconductor chip 14k, the output electrode of the semiconductor chip 14i, and the first wiring portion 13a3 of the first conductive circuit pattern 13a. The bonding wires 17b extend along the first side 12a1 and the second side 12a2.

The bonding wires connecting the control electrodes of the semiconductor chips to the fourth conductive circuit pattern may be made of the same material as the bonding wires described earlier. The diameters of the bonding wires connecting the control electrodes of the semiconductor chips to the fourth conductive circuit pattern may be smaller than those of the bonding wires 17a and 17b. The wiring directions of the bonding wires connecting the control electrodes of the semiconductor chips to the fourth conductive circuit pattern may be substantially orthogonal to those of the bonding wires 17a and 17b.

According to the third embodiment, even in the case where the semiconductor chips are power MOSFETs, the first mounting portion 13a1 and the second mounting portion 13b1 in the semiconductor device may be enlarged as much as possible, as in the first embodiment.

According to one aspect, the mounting areas of semiconductor chips are enlarged.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device, comprising:
a first semiconductor chip having a lower surface and an upper surface;
a second semiconductor chip having a lower surface and an upper surface;
an output terminal, a positive terminal, and a negative terminal; and
an insulated circuit substrate, including:
an insulating plate having an upper surface, the insulating plate having a first side and a second side opposite to each other in a plan view of the semiconductor device, and
a first conductive circuit pattern, a second conductive circuit pattern, and a third conductive circuit pattern that are disposed on the upper surface of the insulating plate, wherein
the first conductive circuit pattern includes:
a first mounting portion on which the lower surface of the first semiconductor chip is mounted, and
a first terminal portion to which the output terminal is bonded;
the second conductive circuit pattern includes:
a second mounting portion on which the lower surface of the second semiconductor chip is mounted, and
a second terminal portion to which the positive terminal is bonded;
the third conductive circuit pattern includes a third terminal portion to which the negative terminal is bonded;
the first mounting portion of the first conductive circuit pattern is located adjacent to the first side of the insulating plate, and the second mounting portion of the second conductive circuit pattern is located adjacent to the second side of the insulating plate, the first mounting portion and the second mounting portion having a gap therebetween; and
the first terminal portion, the second terminal portion, and the third terminal portion are sequentially arranged, parallel to the first side and the second side, in the gap on the upper surface of the insulating plate.

2. The semiconductor device according to claim 1, wherein the gap passes through a center of the upper surface of the insulating plate.

3. The semiconductor device according to claim 1, wherein the first terminal portion, the second terminal portion, and the third terminal portion are aligned in the gap on the upper surface of the insulating plate.

4. The semiconductor device according to claim 1, wherein
the first semiconductor chip includes a first main electrode on the upper surface thereof,
the second semiconductor chip includes a second main electrode on the upper surface thereof,
the first conductive circuit pattern further includes a first wiring portion electrically connected to the second main electrode,
the third conductive circuit pattern further includes a third wiring portion electrically connected to the first main electrode,
the first wiring portion extends from the first terminal portion toward the second side of the insulating plate and is located at a side of the second mounting portion of the second conductive circuit pattern, and
the third wiring portion extends from the third terminal portion toward the first side of said insulating plate and is located at a side of the first mounting portion of the first conductive circuit pattern.

5. The semiconductor device according to claim 4, further comprising:
a first main wiring member connecting the first main electrode of the first semiconductor chip to the third wiring portion of the third conductive circuit pattern, the first main wiring member extending parallel to the first side and the second side; and
a second main wiring member connecting the second main electrode of the second semiconductor chip to the first wiring portion of the first conductive circuit pattern, the second main wiring member extending parallel to the first side and the second side.

6. The semiconductor device according to claim 4, further comprising:
a fourth conductive circuit pattern provided on the upper surface of the insulating plate along the first side of the insulating plate between the first mounting portion of the first conductive circuit pattern and the first side; and
a fifth conductive circuit pattern provided on the upper surface of the insulating plate along the second side of the insulating plate between the second mounting portion of the second conductive circuit pattern and the second side.

7. The semiconductor device according to claim 6, wherein
the first semiconductor chip further includes a first control electrode on one side of the upper surface thereof, the first semiconductor chip being mounted on the first mounting portion such that the first control electrode faces away from the third wiring portion,
the second semiconductor chip further includes a second control electrode on one side of the upper surface thereof, the second semiconductor chip being mounted on the second mounting portion such that the second control electrode faces away from the first wiring portion, and
the semiconductor device further includes
a first control wiring member extending from the first control electrode of the first semiconductor chip toward the first side to connect the first control electrode to the fourth conductive circuit pattern, and
a second control wiring member extending from the second control electrode of the second semiconductor chip toward the second side to connect the second control electrode to the fifth conductive circuit pattern.
